(19) United States
(12) Patent Application Publication
(10) Pub. No.: US 2026/0090359 A1
(43) Pub. Date: Mar. 26, 2026

(54) BEOL Power Switch Devices

(71) Applicant: Apple Inc., Cupertino, CA (US)

(72) Inventors: Xin Miao, Saratoga, CA (US); Shingo Suzuki, San Jose, CA (US); Saurabh P. Sinha, Austin, TX (US)

(21) Appl. No.: 19/337,246

(22) Filed: Sep. 23, 2025

Related U.S. Application Data
(60) Provisional application No. 63/697,670, filed on Sep. 23, 2024.

(51) Int. Cl. H01L 23/528; H10D 64/23

(52) U.S. Cl. CPC H10W 20/427; H10D 64/251

(57) ABSTRACT

Integrated circuit devices with power switch circuits formed between topside BEOL (back end of line) metal layers are described. The power switch circuits include active regions and source/drains that can be formed in the spaces between topside metal layers. In certain instances, the power switch circuits are formed in between metal layers furthest away from substrate. The power switch circuits connect to control signal and power routing either above or below the transistors. In various instances, the active regions of the power switch circuits are formed by thin channel materials.

### PRIORITY CLAIM

The present application claims priority to U.S. Provisional App. No. 63/697,670, entitled “BEOL Power Switch Devices,” filed Sep. 23, 2024, the disclosure of which is incorporated by reference herein in its entirety.

### BACKGROUND

### Technical Field

Embodiments described herein relate to power and signal routing for semiconductor devices. More particularly, embodiments described herein relate to implementation of power switch circuit transistors in topside metal layers such as BEOL (“back end of line”) metal layers.

### Description of the Related Art

Power switch circuits are important in large scale integrations of integrated circuits (such as very-large scale integrations (VLSIs)). For instance, power switches are implemented to convert true power supply voltages (e.g., true VDD or TVDD) provided by power supplies to virtual power supply voltages that are tailored for specific devices. Current implementations of power switch devices are placed in transistor regions of integrated circuit devices, which means long vias (e.g., via towers) are needed to route power supply voltages to/from the power switch devices. The long vias may pass through many metal layers and can cause IR drop as well as providing physical blockages for design routing and placement of components. Additionally, having the power switches in the transistor regions themselves takes up valuable silicon-area real estate in the integrated circuit devices. Thus, there are both electrical and mechanical issues associated with current implementations of power switch devices that can be improved.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a top view representation of a contemplated device with a power switch circuit in between topside metal layers, according to some embodiments.

FIG. 2 is a cross-sectional side-view representation of a device showing a portion of a power switch circuit with a gate along line 2-2 in FIG. 1, according to some embodiments.

FIG. 3 is a cross-sectional side-view representation of a device showing a portion of a power switch circuit with a source along line 3-3 in FIG. 1, according to some embodiments.

FIG. 4 is a cross-sectional side-view representation of a device showing a portion of a power switch circuit with a drain along line 4-4 in FIG. 1, according to some embodiments.

FIG. 5 depicts a top view representation of another contemplated device with a power switch circuit in between topside metal layers, according to some embodiments.

FIG. 6 is a cross-sectional side-view representation of a device showing a portion of a power switch circuit with a gate along line 6-6 in FIG. 5, according to some embodiments.

FIG. 7 is a cross-sectional side-view representation of a device showing a portion of a power switch circuit with a source along line 7-7 in FIG. 5, according to some embodiments.

FIG. 8 is a cross-sectional side-view representation of a device showing a portion of a power switch circuit with a drain along line 8-8 in FIG. 5, according to some embodiments.

FIG. 9 depicts a top view representation of another contemplated device with a power switch circuit in between topside metal layers with the power switch circuit having some connections to a lower topside metal layer, according to some embodiments.

FIG. 10 is a cross-sectional side-view representation of a device showing a portion of a power switch circuit with a gate along line 10-10 in FIG. 9, according to some embodiments.

FIG. 11 is a cross-sectional side-view representation of a device showing a portion of a power switch circuit with a source along line 11-11 in FIG. 9, according to some embodiments.

FIG. 12 is a cross-sectional side-view representation of a device showing a portion of a power switch circuit with a drain along line 12-12 in FIG. 9, according to some embodiments.

FIG. 13 depicts a top view representation of yet another contemplated device with a power switch circuit in between topside metal layers with the power switch circuit having some connections to a lower topside metal layer, according to some embodiments.

FIG. 14 depicts a top view representation of a contemplated device with a power switch circuit in between topside metal layers with the power switch circuit converting power in the same metal layer, according to some embodiments.

FIG. 15 is a cross-sectional side-view representation of a device showing a portion of a power switch circuit with a gate along line 15-15 in FIG. 14, according to some embodiments.

FIG. 16 is a cross-sectional side-view representation of a device showing a portion of a power switch circuit with a source along line 16-16 in FIG. 15, according to some embodiments.

FIG. 17 is a cross-sectional side-view representation of a device showing a portion of a power switch circuit with a drain along line 17-17 in FIG. 15, according to some embodiments.

FIG. 18 depicts an example representation of a current power switch circuit implementation where the power switch circuits are positioned in a transistor region of the device.

FIG. 19 depicts a representation of a power switch circuit implementation where the power switch circuits are positioned in the BEOL layers of the device according to the various embodiments described herein.

FIGS. 20A-C are cross-sectional side-view representations of a first manufacturing step of a power switch circuit positioned between two topside metal layers, according to some embodiments.

FIGS. 21A-C are cross-sectional side-view representations of a second manufacturing step of a power switch circuit positioned between two topside metal layers, according to some embodiments.

FIGS. 22A-C are cross-sectional side-view representations of a third manufacturing step of a power switch circuit positioned between two topside metal layers, according to some embodiments.

FIGS. 23A-C are cross-sectional side-view representations of a fourth manufacturing step of a power switch circuit positioned between two topside metal layers, according to some embodiments.

FIGS. 24A-C are cross-sectional side-view representations of a fifth manufacturing step of a power switch circuit positioned between two topside metal layers, according to some embodiments.

FIGS. 25A-C are cross-sectional side-view representations of a sixth (final) manufacturing step of a power switch circuit positioned between two topside metal layers, according to some embodiments.

FIG. 26 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to the implementation of power switch circuits in between metal layers above a transistor region (e.g., topside metal layers) of integrated circuit devices. In various embodiments, these topside metal layers may be referred to as BEOL (“back end of line”) metal layers. The topside metal layers may provide routing (e.g., paths) for control signals and/or power signals. Many current designs of cells provide connections and routing for power or signals to transistors or other structures in areas above the transistors. For example, the connections and routing for power or signals may be provided in topside layers of the device. As used herein, the term “topside” refers to areas in a device that are vertically above an active layer of the device (e.g., above a transistor region of the device when viewed in a typical cross-sectional view). For example, topside may refer to components such as contacts or layers that are above a transistor region in a vertical dimension, as depicted in the figures and described herein. In some instances, the term “frontside” may be used interchangeably with the term “topside”.

As used herein, the term “routing” refers to any combination of metal vias, metal wires, metal traces, etc. that provide a path/route between two structures. Additional embodiments may be contemplated where the metal in “routing” is replaced with an alternative conductive material. For instance, the metal in “routing” may be replaced with a superconductor material, a semiconductor material, or a non-metal conductor.

Power switch circuits are implemented in many current iterations of VLSI (“very large scale integration”) devices. For low power VLSI devices, power switch circuits are essential in converting higher power supply voltages to lower operating voltages for specific devices in the VLSI. For instance, power switch circuits may convert the actual power supply voltage (referred to, herein, as “true supply voltage” or “TVDD”) from a power supply source to a lower supply voltage (referred to, herein, as “virtual supply voltage” or “VVDD”) that is usable for operation of specific devices. Current implementations of power switch circuits place the power switch circuits in the transistor regions of integrated circuit devices. Placing power switch circuits in transistor regions of integrated circuit devices in large scale integrations may, however, cause electrical (e.g., IR drop) and mechanical (e.g., footprint/area utilization and path blockage) issues due to the use of via towers and long travel paths to route voltage signals to/from the power switches as well as the placement of the power switches in the transistor regions themselves.

The present disclosure recognizes that these issues may be alleviated by placing power switch circuits in locations between topside routing layers (e.g., topside metal routing layers) instead of in the transistor regions of the integrated circuit devices. Placing the power switch circuits in these locations allows connections between the power switch circuits and their associated power supplies to be more localized and limited to areas above the transistor regions. Thus, there is minimal need for via towers or other structures and the path length for power supply voltages is reduced. Additionally, placing the power switch circuits in the topside metal routing layers removes the power switch circuits from the transistor region of the integrated circuit devices, opening up large amounts of silicon transistor real estate (e.g., footprint) for additional components or structures.

The opened up footprint may be utilized, for example, to increase the number of other types of transistors or circuit elements, allowing for more complex or powerful devices. Additionally, moving the power switch circuits out of the transistor regions of the devices eliminates potential blockages by the power switch circuits. Opening up the footprint and removing blockages may allow more flexibility in the design or manufacturing of integrated circuit devices. For instance, the design of integrated circuits may include more optimized routing strategies for signals in the devices with the opening up of the footprint and removal of blockages. Manufacturing may also be more efficient in certain instances with optimized design strategies.

Certain embodiments disclosed herein have three broad elements: 1) a transistor region; 2) first and second metal layers in topside metal layers above the transistor region where the first metal layer includes power supply routing and the second metal layer includes control signal routing, and 3) a power switch circuit positioned between the first and second metal layers. In certain embodiments, the routing in the first metal layer is orthogonal to the routing in the second metal layer. The first metal layer may be above or below the power switch circuit with the second metal layer being the corresponding layer below or above the power switch circuit. In various embodiments, the power switch circuit includes an active region with a gate, a source, and a drain formed over the active region. The gate may be coupled to the control signal routing and the source region may be coupled to the power supply routing providing true power supply voltage (TVDD) from the power supply. The drain region may output the virtual power supply voltage (VVDD) to one or more transistor circuits via power routing (e.g., output power routing) coupled to the drain region.

Various illustrations of embodiments with these broad elements are now described in the present disclosure. It should be noted that the illustrated embodiments of the present disclosure depict design templates for devices with power switch transistors positioned in between topside metal layers. These design templates provide basic building blocks from which many different types of routing schemes for devices may be constructed based on connection schemes to the power switch circuits in the design templates.

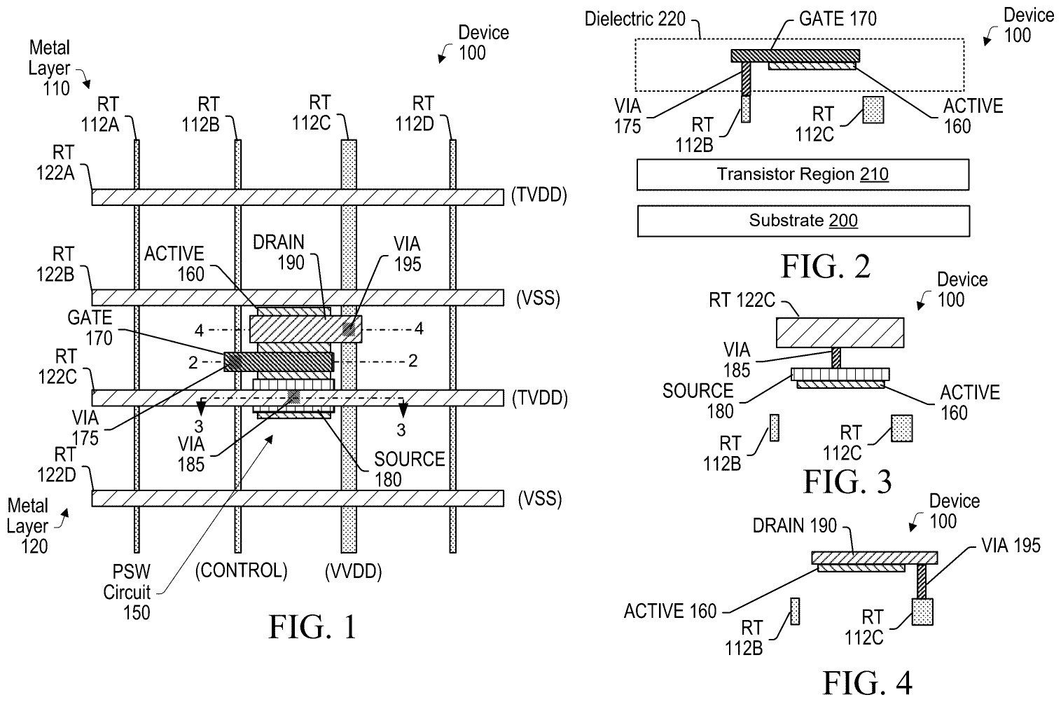

FIG. 1 depicts a top view representation of a contemplated device with a power switch circuit in between topside metal layers, according to some embodiments. In the illustrated embodiment, two topside metal layers 110 and 120 for device 100 are shown. Metal layers 110 and 120 may be, for example, topside BEOL metal layers vertically above a transistor region and a substrate of device 100. In certain embodiments, metal layer 110 is the topside metal layer that is vertically closer to the transistor region of device 100 and metal layer 120 is the topside metal layer that is vertically further from the transistor region. Accordingly, with power switch (PSW) circuit 150 positioned between metal layers 110 and 120, metal layer 110 is a “bottom” or “below” metal layer and metal layer 120 is a “top” or “above” metal layer relative to the power switch circuit above a substrate of device 100. Embodiments may be contemplated, however, where the bottom and top metal layers are reversed—e.g., metal layer 110 is the top metal layer above power switch circuit 150 and metal layer 120 is the bottom metal layer below the power switch circuit.

In various embodiments, metal layer 110 includes routings (“RT”) 112A-D and metal layer 120 includes routings (“RT”) 122A-D. As metal layer 110 and metal layer 120 are neighboring metal layers in the topside metal layers, routings 112A-D and routings 122A-D may run perpendicular (e.g., orthogonal) to each other, as shown in FIG. 1. Routings 112A-D and routings 122A-D may include signal routing (e.g., control signal routing), power supply routing, ground supply routing, or other routings, as described herein.

The types and placement of routings in device 100 may be dependent on the placement and structure of a power switch circuit (e.g., power switch circuit 150, described below) positioned in between the metal layers. For instance, various arrangements of routings for control signal routing, power supply routing, and ground supply routing are depicted herein with the arrangement of the routings being dependent on the structure of the power switch circuit and the relationship between the power switch structure and the routings. In some embodiments, one or more of the routings 112 and routings 122 are global routings. Global routings may be, for example, routes that carry signals over long distances and try to avoid diversions in their pathways when passing above transistor regions to which they are not connected.

In the illustrated embodiment of FIG. 1, device 100 includes power switch circuit 150 positioned in the space vertically between metal layer 110 and metal layer 120. In certain embodiments, power switch circuit 150 includes active region 160. In some embodiments, active region 160 is positioned between routing 112B and routing 112C in a horizontal direction. Routing 112B may be a routing for a control signal (“control”) for power switch circuit 150 while routing 112C is a routing for virtual power supply voltage (“VVDD”) output from the power switch circuit. In certain embodiments, routing for VVDD output from power switch circuit 150 may be referred to as “output power routing”. Routing 112A and routing 112D may be other routings such as global routings. Active region 160 may also be horizontally between routing 122B and routing 122C with a portion of the active region extending under routing 122C for connection to the routing (as described herein). In the illustrated embodiment, routing 122A and routing 122C are power supply (“TVDD”) routing and routing 122B and routing 122D are ground supply (“VSS”) routing while routing 112B is control signal routing. In certain embodiments, routing for TVDD input to power switch circuit 150 may be referred to as “power supply routing”.

As described above, routing 122B may be routing for ground supply voltage (“VSS”) while routing 122C is routing for power supply voltage (“TVDD”) from a power supply source that is input to the power switch circuit. It should be understood, however, that the exact placement of active region 160 may vary, for example, depending on where and how connections to the various components of power switch circuit 150 are implemented. Additionally, while additional routings are labelled with possible types of routings—e.g., routing 122A with TVDD and routing 122D with VSS—these routing labels are provided as examples and exact routings throughout device 100 may vary.

In certain embodiments, active region 160 of power switch circuit 150 is an active region made of thin channel materials. For example, the channel materials may be on the order of one or more atomic layers. Thin channel materials may include materials such as, but not limited to, 2D (two-dimensional) materials, CNTs (carbon nano-tubes), and oxide semiconductors. Examples of 2D materials include, but are not limited to, graphene, silicene, BNNS (boron nitride nanosheets), TMDCs (transition-metal dichalcogenides), phosphorene, and metal oxide nanosheets. Utilizing these types of materials may allow similar active region characteristics to silicon to be achieved in a few layers that can be positioned between existing topside metal layers in a device layout. Power switch circuits with these types of active regions and positioned between topside metal layers, as described herein, may be implemented in various designs of devices with the power switch circuits placed at various locations in devices (such as device 100) to provide power switch (e.g., power conversion) operations at various positions across the devices.

In the illustrated embodiment of FIG. 1, power switch circuit 150 includes gate 170, source 180, and drain 190 formed over active region 160. Together, gate 170, source 180, and drain 190, along with active region 160, form the transistor of power switch circuit 150 for converting TVDD to VVDD. In various embodiments, gate 170, source 180, and drain 190 are oriented along a direction of routing 122 in metal layer 120 (e.g., the gate, source, and drain are oriented in parallel to the routing). Additionally, source 180 may be positioned along the same path as routing 122C to allow direct vertical contact between the source and the routing.

FIG. 2 is a cross-sectional side-view representation of device 100 showing a portion of power switch circuit 150 with gate 170 along line 2-2 in FIG. 1, according to some embodiments. Note that some elements in device 100 (such as, but not limited to, substrate 200, transistor region 210, and dielectric 220) are shown representatively for illustrative purposes and that their dimensions and spacing relative to each other may vary. Additionally, for convenience in the drawings, substrate 200, transistor region 210, and dielectric 220 are shown only in FIG. 2 with the understanding that these elements of device 100 translate to the embodiments of the additional figures.

In various embodiments, metal layer 110 and metal layer 120 (e.g., the topside/BEOL metal layers) along with the components of power switch circuit 150 are positioned above transistor region 210 and substrate 200 (note only routings 112 of metal layer 110 are shown in the cross-section of FIG. 2 but that metal layer 120 would be vertically above metal layer 110). In certain embodiments, metal layer 110 and metal layer 120 are lower metal layers. For instance, metal layer 110 and metal layer 120 may be metal layers that are vertically closer to transistor region 210 than other metal layers (e.g., there are additional metal layers above metal layer 120). Placing power switch 150 in between BEOL/topside metal layers closer to the transistor region 210 may reduce the travel path for VVDD, thus reducing resistance for transmitting VVDD and reducing voltage drop. Metal layer 110 and metal layer 120 may, however, be any pair of adjacent (e.g., vertically neighboring) metal layers positioned above transistor region 210. For instance, embodiments may be contemplated where metal layer 110 and metal layer 120 are the two metal layers vertically further away from transistor region 310.

In certain embodiments, a layer of dielectric 220 is positioned between metal layer 110 and metal layer 120. Dielectric 220 may include any suitable dielectric material for providing electrical insulation and mechanical support between metal layer 110 and metal layer 120. For instance, dielectric 220 may include silicon oxide. Power switch circuit 150, including active region 160, gate 170, source 180, and drain 190, may be formed between metal layer 110 and metal layer 120 and surrounded, at least partially, by dielectric 220.

In the illustrated embodiment of FIG. 2, gate 170 includes gate material that is positioned over active region 160 and extends over routing 112B (e.g., the control signal routing). With the gate material extending, via 175 (also shown in FIG. 1) may connect gate 170 to routing 112B in a direct vertical path for control signal input to the gate of power switch circuit 150. As shown in FIG. 2, via 175 may provide connection from inside dielectric 220, where the components of power switch circuit 150 are located, to outside the dielectric where the metal layer routings are located.

Turning back to FIG. 1, source 180 is formed over active region 160 and on one side of gate 170. Source 180 is also formed underneath a portion of routing 122C (“TVDD”). FIG. 3 is a cross-sectional side-view representation of device 100 showing a portion of power switch circuit 150 with source 180 along line 3-3 in FIG. 1, according to some embodiments. In the illustrated embodiment, source 180 is formed over active region 160 and via 185 (also shown in FIG. 1) connects the source to routing 122C in a direct vertical path, which is directly above the source. The connection between routing 122C and source 180 provides TVDD as input to the source of power switch circuit 150.

Turning back to FIG. 1, drain 190 is formed over active region 160 and on an opposite side of gate 170 from source 180. FIG. 4 is a cross-sectional side-view representation of device 100 showing a portion of power switch circuit 150 with drain 190 along line 4-4 in FIG. 1, according to some embodiments. In the illustrated embodiment, drain 190 is formed over active region 160 and extends above routing 112C. Via 195 (also shown in FIG. 1) connects drain 190 to routing 112C in a direct vertical path to connect the routing for VVDD to the output of power switch circuit 150.

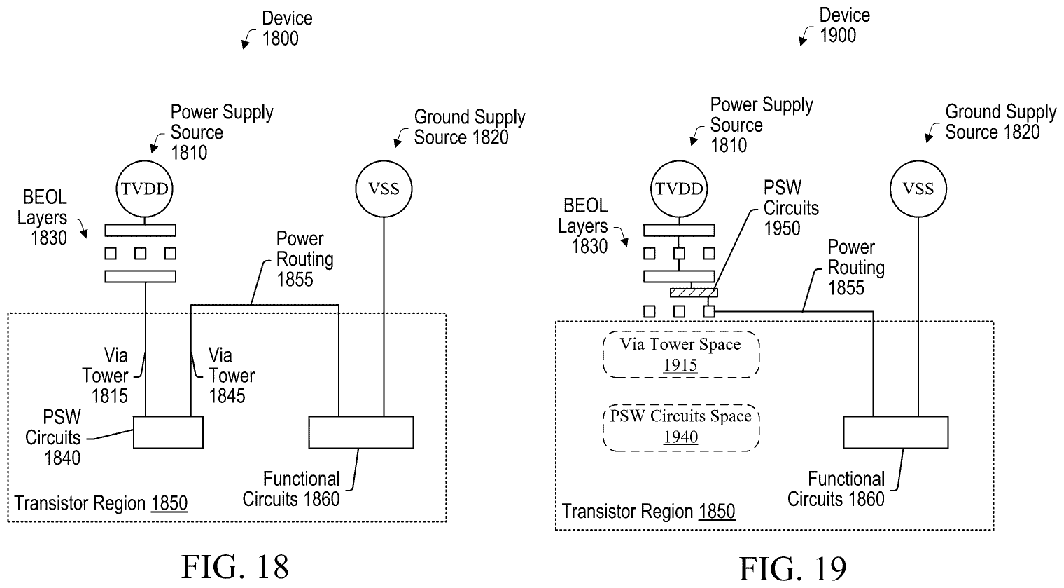

With the various connections made between the components of power switch circuit 150 (e.g., gate 170, source 180, drain 190) and the routings in the metal layers above/below the power switch circuit, the power switch circuit provides a localized power switch within a grid of routings (e.g., the grid of routing 112B, routing 112C, routing 122B and routing 122C of FIG. 1). Placing the power switch within the boundaries of the grid of routings does not block any via accesses around the perimeter of the power switch circuit. Further, power switch 150 connects to a control signal that runs parallel to the output VVDD signal. Accordingly, multiple power switches may be connected to in parallel using the single set of routings for the control signal (routing 112B) and VVDD (routing 112C). Having multiple power switch circuits connected in parallel may provide a design path for generating total drive strengths sufficient for functional circuits in the transistor region (note, however, that multiple different TVDD routings may be necessary for connection to the multiple power switch circuits). Additionally, the power switch circuit being located in the BEOL/topside metal layers allows the power switch to have shorter signal paths to functional circuits in the transistor region, thereby reducing resistance for VVDD transmission and increasing available footprint. Further discussion of these advantages and additional advantages are discussed below with reference to FIGS. 18 and 19.

In some embodiments, the size of the active region of the power switch circuit may be varied to change the power switching capacity (e.g., drive strength or ‘on’ resistance) of the power switch circuit. The size of the gate, source, and drain may be adapted to adjust to the change in size of the active region. Increasing the size of these components may also allow for changes in connection arrangements to the components. The availability of increasing the area of the active region may depend on the availability of where placements of different routings are—e.g., where placement of TVDD or VVDD are for connecting to the power switch circuit.

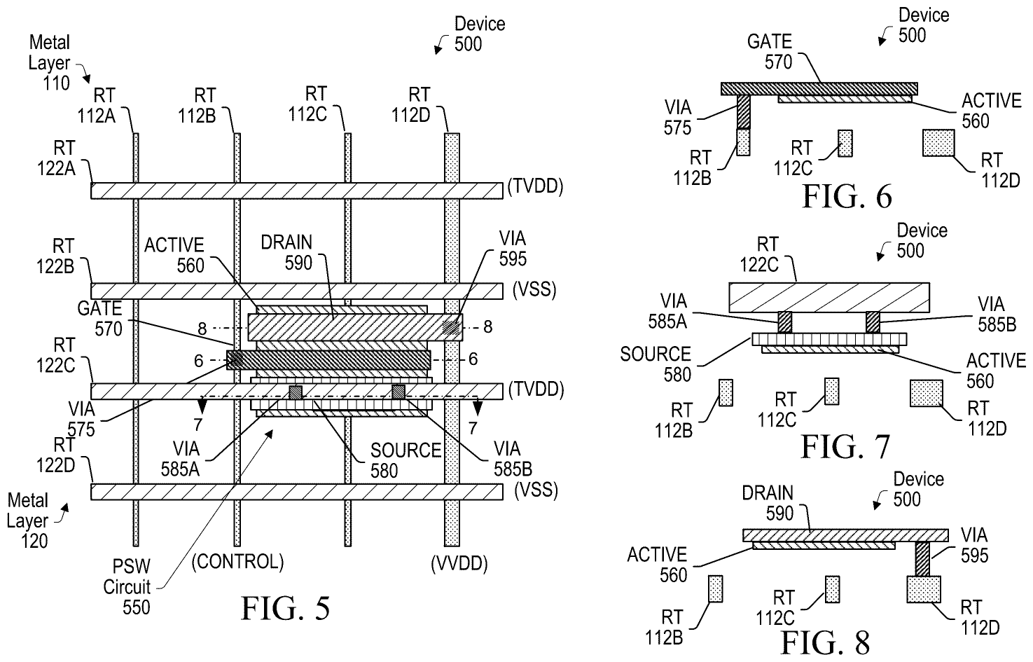

FIG. 5 depicts a top view representation of another contemplated device with a power switch circuit in between topside metal layers, according to some embodiments. In the illustrated embodiment, device 500 includes power switch (PSW) circuit 550 that has active region 560 with an increased area compared to power switch 150, shown in FIG. 1. In this contemplated embodiment, VVDD is moved from routing 112C (as shown in FIG. 1) to routing 112D. This movement of VVDD routing allows active region 560 to span approximately the width of two routing spacings between routing 112B and routing 112D while crossing over routing 112C.

With the increased area (width) of active region 560, gate 570, source 580, and drain 590 also have increased widths. FIG. 6 is a cross-sectional side-view representation of device 500 showing a portion of power switch circuit 550 with gate 570 along line 6-6 in FIG. 5, according to some embodiments. In the illustrated embodiment, gate 570 is above active region 560 with both being above routing 112C. Gate 570 further has gate material that extends to above routing 112B (e.g., the control signal routing). Via 575 (also shown in FIG. 5) connects gate 570 to routing 112B for control signal input to the gate of power switch circuit 550. Note that some elements in device 500 (such as, but not limited to, a substrate, a transistor region, and a dielectric) are not shown for convenience but are previously described above with respect to FIG. 2.

FIG. 7 is a cross-sectional side-view representation of device 500 showing a portion of power switch circuit 550 with source 580 along line 7-7 in FIG. 5, according to some embodiments. In the illustrated embodiment, source 580 is formed over active region 560 between routing 112B and routing 112D. With the increased area (width) of source 580, there is availability for two vias to connect source 580 to routing 122C (“TVDD”). Accordingly, both via 585A and via 585B (also shown in FIG. 5) connect source 580 to routing 122C, which is directly above the source along the length of the source. The connection between routing 122C and source 580 provides TVDD as input to the source of power switch circuit 550.

FIG. 8 is a cross-sectional side-view representation of device 500 showing a portion of power switch circuit 550 with drain 590 along line 8-8 in FIG. 5, according to some embodiments. In the illustrated embodiment, drain 590 is formed over active region 560 and both are positioned above routing 112C. Drain 590 further extends to above routing 112D. Via 595 (also shown in FIG. 5) then connects drain 590 to routing 112D to connect the routing for VVDD to the output of power switch circuit 550.

FIGS. 5-8 shown an example of one embodiment where the size of the active region is increased to increase the drive strength or reduce the ‘on’ resistance of the power switch circuit. In the illustrated example, VVDD is moved over one routing spacing to allow the active region to be increased in size width-wise (e.g., horizontally in the illustrations). Additional embodiments may be contemplated where the spacing of TVDD is increased to allow increases height-wise (vertically in the illustration) of the active region. Combinations of width and height increases may also be contemplated to increase the size of the active region and thus the drive strength of the power switch circuit.

Additional embodiments may be contemplated where some of the connections for a power switch circuit are made to routings in metal layers in the next metal layer below the metal layer immediately below the power switch circuit (e.g., the next metal layer vertically below metal layer 110 in the previous illustrations). Moving the connections to this next lower metal layer allows the routings being connected with to be in parallel to the routings connected with above the power switch circuit that are in the above metal layer (e.g., metal layer 120). Having parallel routings to/from the power switch circuit may allow more direct routing into/out of the power switch circuit and provide some improved electrical properties with regards to shielding between the routes. Additionally, having all three routings (TVDD, VVDD, control signal) for connections to the power switch circuit in parallel allows multiple power switches to be connected to in parallel with one of each routing for all the parallel power switches.

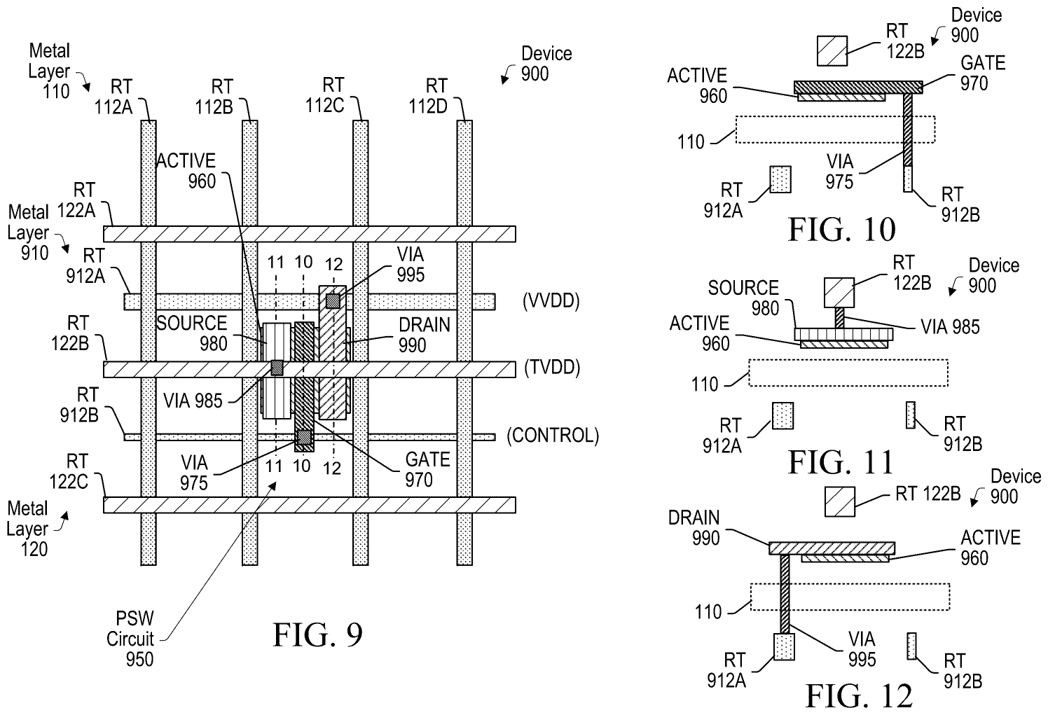

FIG. 9 depicts a top view representation of another contemplated device with a power switch circuit in between topside metal layers with the power switch circuit having some connections to a lower topside metal layer, according to some embodiments. In the illustrated embodiment, device 900 includes power switch (PSW) circuit 950. Power switch circuit 950 includes active region 960 with gate 970, source 980, and drain 990 formed over the active region between metal layer 110 and metal layer 120.

In the contemplated embodiment, routing for the control signal input to power switch circuit 950 and VVDD output from the power switch circuit are moved to a lower metal layer-metal layer 910. Metal layer 910 is a metal layer below metal layer 110 (e.g., the next metal layer below metal layer 110). Thus, metal layer 910 has routing that is parallel to the routing in metal layer 120 and perpendicular (e.g., orthogonal) to the routing in metal layer 110. In the illustrated embodiment, metal layer 910 includes routing (RT) 912A for VVDD routing and routing (RT) 912B for control signal routing. Accordingly, both VVDD routing and control signal routing are in parallel to TVDD routing (routing 122B) in metal layer 120.

FIG. 10 is a cross-sectional side-view representation of device 900 showing a portion of power switch circuit 950 with gate 970 along line 10-10 in FIG. 9, according to some embodiments. In the illustrated embodiment, gate 970 is above active region 960 with both being above metal layer 110. Gate 970 has gate material that extends to above routing 912B (e.g., the control signal routing). Via 975 (also shown in FIG. 9) connects gate 970 to routing 912B by passing through metal layer 110 for control signal input to the gate of power switch circuit 950. Note that some elements in device 900 (such as, but not limited to, a substrate, a transistor region, and a dielectric) are not shown for convenience but are previously described above with respect to FIG. 2.

FIG. 11 is a cross-sectional side-view representation of device 900 showing a portion of power switch circuit 950 with source 980 along line 11-11 in FIG. 9, according to some embodiments. In the illustrated embodiment, source 980 is formed over active region 960 between routing 912A and routing 912B and above metal layer 110. Note that routing 122B goes into/out of the page in the illustrated embodiment. Via 985 (also shown in FIG. 9) connect sources 980 to routing 122B, which passes over the source near a center of the source. The connection between routing 122B and source 980 provides TVDD as input to the source of power switch circuit 950.

FIG. 12 is a cross-sectional side-view representation of device 900 showing a portion of power switch circuit 950 with drain 990 along line 12-12 in FIG. 9, according to some embodiments. In the illustrated embodiment, drain 990 is formed over active region 960 and both are positioned above metal layer 110. Drain 990 extends to above routing 912A. Via 995 (also shown in FIG. 9) then connects drain 990 to routing 912A by passing through metal layer 110 to connect the routing for VVDD to the output of power switch circuit 950.

As shown in FIGS. 9-12, with TVDD, VVDD, and control signal routing all being in parallel, active region 960 may be positioned vertically below the TVDD routing (routing 122B) in metal layer 120 and above metal layer 110 while being horizontally between the VVDD routing (routing 912A) and the control signal routing (routing 912B). Gate 970, source 980, and drain 990 are oriented perpendicular to these routing paths (e.g., vertically in the illustration). This design places power switch circuit 950 within the grids of routing 112B, routing 112C, routing 912A, and routing 912B and does not block any via accesses within this grid.

Additionally, routings for the control signal, the TVDD signal, and the VVDD signal to power switch circuit 950 all run in parallel. Accordingly, multiple power switch circuits may be easily connected to in parallel using the parallel routings with each power switch circuit being positioned horizontally between routing 912A and routing 912B. As mentioned above, having multiple power switch circuits connected in parallel may provide a design path for generating total drive strengths sufficient for functional circuits in the transistor region. With the routings for the control signal, the TVDD signal, and the VVDD signal being in parallel, the multiple power switch circuits may have one common TVDD routing, one common control signal routing, and one common VVDD routing for simpler design construct in the BEOL/topside metal layers.

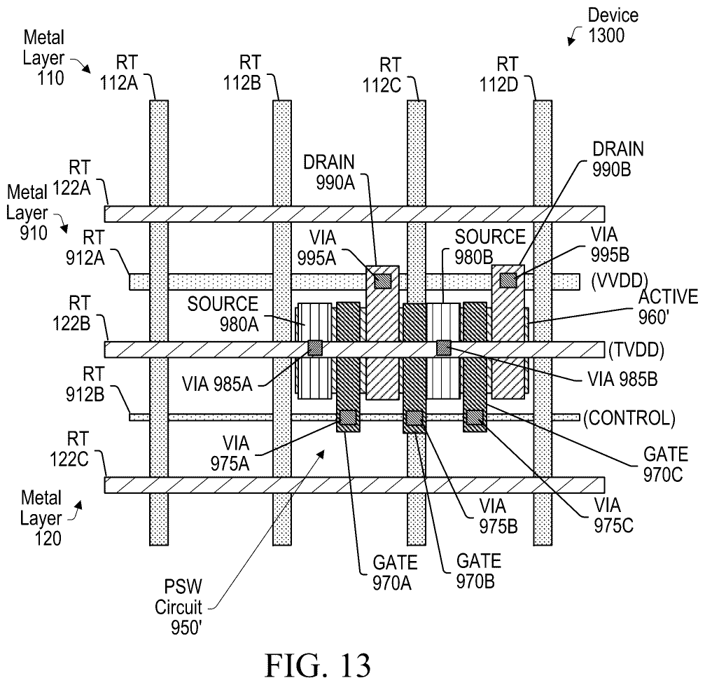

FIG. 13 depicts a top view representation of yet another contemplated device with a power switch circuit in between topside metal layers with the power switch circuit having some connections to a lower topside metal layer, according to some embodiments. In the illustrated embodiment, device 1300 includes power switch (PSW) circuit 950′ where active region 960′ is increased in length (e.g., horizontally in the illustration) relative to the embodiment depicted in FIG. 9. With the increase in length of active region 960′, multiple gates may be formed over the active region where the gates shared some of the source/drain regions.

For instance, as shown in FIG. 13, gates 970A, 970B, 970C, sources 980A and 980B, and drains 990A and 990B may be formed over active region 960′. Gate 970A may have source 980A to itself but shares drain 990A with gate 970B. Gate 970B may share drain 990A with gate 970A and also share source 980B with gate 970C. Gate 970C then shares source 980B but has its own drain 990B. In the illustrated embodiment, gates 970A, 970B, 970C are coupled to a common control signal routing (routing 912B) by vias 975A, 975B, 975C, respectively. Thus, a common control signal is provided to all three gates and the gates operate in parallel. Source 980A and source 980B are also coupled to a common TVDD routing (routing 122B) by via 985A and via 985B, respectively, for a common input to the sources. Yet further, drain 990A and drain 990B are coupled to a common VVDD routing (routing 912A) by via 995A and via 995B, respectively, for a common output from the drains and power switch circuit 950′. It should be noted that, as with power switch circuit 950 (shown in FIG. 9), multiple power switch circuits 950′ may be positioned in parallel between routing 912A and routing 912B with the multiple power switch circuits being connected to a common control signal, a common VVDD signal, and a common TVDD signal.

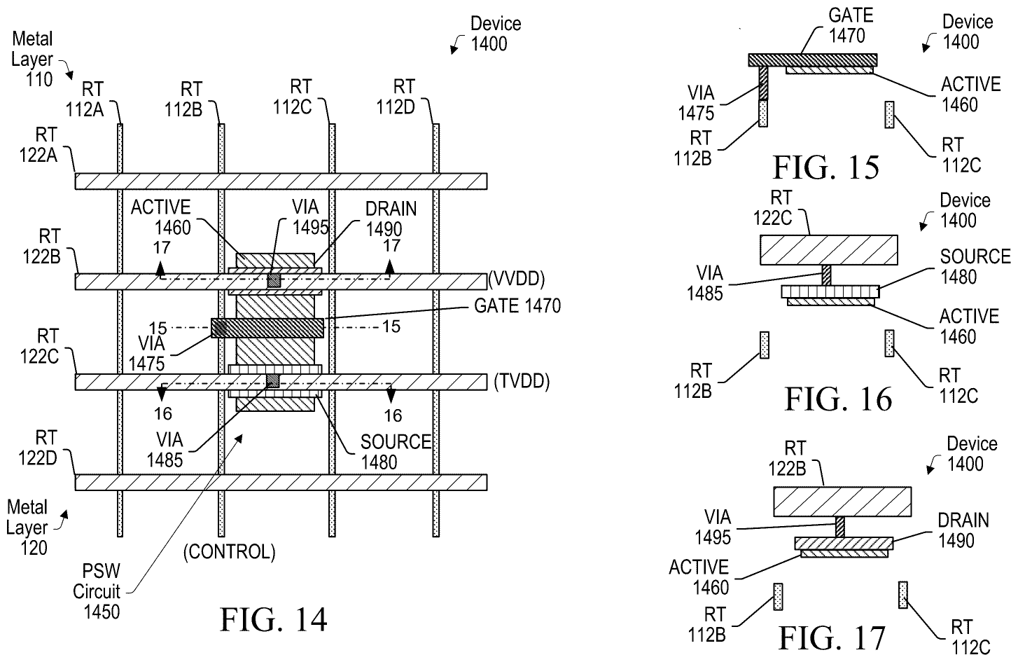

Yet other embodiments may be contemplated where the conversion from TVDD to VVDD occurs in the same layer of routing using a power switch circuit in the BEOL/topside metal layers. FIG. 14 depicts a top view representation of a contemplated device with a power switch circuit in between topside metal layers with the power switch circuit converting power in the same metal layer, according to some embodiments. In the illustrated embodiment, device 1400 includes power switch (PSW) circuit 1450 where active region 1460 extends between and beyond routing 122B and routing 122C in metal layer 120. In certain embodiments, routing 122C is routing for TVDD and routing 122B is routing for VVDD. Accordingly, both the routing for TVDD and the routing for VVDD are positioned in the same metal layer. This routing arrangement allows power switch circuit 1450 to convert power in the same metal layer. Control signal routing, however, may be positioned in another metal layer (e.g., metal layer 110 and routing 112B) to maintain a reduced size for power switch circuit 1450 and inhibit via path blockage by the power switch circuit.

In the illustrated embodiment of FIG. 14, power switch circuit 1450 includes gate 1470, source 1480, and drain 1490 formed over active region 1460. In various embodiments, gate 1470, source 1480, and drain 1490 are oriented along a direction of routing 122 in metal layer 120 (e.g., the gate, source, and drain are oriented in parallel to the routing). Additionally, source 1480 may be positioned along the same path as routing 122C to allow direct vertical contact between the source and its corresponding TVDD routing. Similarly, drain 1490 may be positioned along the same path as routing 122B to allow direct vertical contact between the drain and its corresponding VVDD routing.

FIG. 15 is a cross-sectional side-view representation of device 1400 showing a portion of power switch circuit 1450 with gate 1470 along line 15-15 in FIG. 14, according to some embodiments. In the illustrated embodiment, gate 1470 is above active region 1460. Gate 1470 has gate material that extends to above routing 112B (e.g., the control signal routing). Via 1475 (also shown in FIG. 14) connects gate 1470 to routing 112B for control signal input to the gate of power switch circuit 1450. Note that some elements in device 1400 (such as, but not limited to, a substrate, a transistor region, and a dielectric) are not shown for convenience but are previously described above with respect to FIG. 2.

FIG. 16 is a cross-sectional side-view representation of device 1400 showing a portion of power switch circuit 1450 with source 1480 along line 16-16 in FIG. 14, according to some embodiments. In the illustrated embodiment, source 1480 is formed over active region 1460 and via 1485 (also shown in FIG. 14) connects the source to routing 122C, which is directly above the source, in a direct vertical path. The connection between routing 122C and source 1480 provides TVDD as input to the source of power switch circuit 1450.

FIG. 17 is a cross-sectional side-view representation of device 1400 showing a portion of power switch circuit 1450 with drain 1490 along line 17-17 in FIG. 14, according to some embodiments. In the illustrated embodiment, drain 1490 is formed over active region 1460 and via 1495 (also shown in FIG. 14) connects the drain to routing 122B, which is directly above the source, in a direct vertical path. The connection between routing 122B and drain 1490 provides VVDD as an output from power switch circuit 1450 that is in the same metal layer of routing as TVDD.

The various power switch circuits described herein are positioned in the BEOL/topside metal layers of integrated circuit devices that are above transistor regions where functional circuits are generally located. Placing the power switch circuits provides in the BEOL metal layers provides various advantages over typical current techniques for power switch circuits that place the power switch circuits in the transistor region/functional circuit area of the devices. The transistor region/functional circuit area of integrated circuit devices is a high-value area of silicon real estate. It may be a better utilization of resources to use such high-value silicon real estate for valuable functional circuits rather than less valuable power switch circuits.

FIGS. 18 and 19 are examples illustrating some of the differences between current techniques of power switch circuit implementation versus the various embodiments of power switch circuit implementation described herein. FIG. 18 depicts an example representation of a current power switch circuit implementation where the power switch circuits are positioned in a transistor region of the device. In the illustrated embodiment, device 1800 includes power supply source (TVDD) 1810 and ground supply source (VSS) 1820 positioned above BEOL layers 1830. Power switch (PSW) circuits 1840 are positioned in transistor region 1850 along with functional circuits 1860. As mentioned above, transistor region 1850 includes high-value silicon real estate for device 1800. Thus, power switch circuits 1840 are occupying high-value silicon real estate in transistor region 1850.

For power switch circuits 1840 to operate, routes are needed both from power supply source 1810 to receive TVDD and to functional circuits 1860 to provide VVDD to the functional circuits. With power switch circuits 1840 positioned in transistor region 1850, the route from power supply source 1810 to the power switch circuits 1840 is provided by via tower 1815. The route from power switch circuits 1840 to functional circuits 1860 is through via tower 1845 and power routing 1855 (e.g., output power routing).

Via tower 1815 and via tower 1845 may be collection of vias going through transistor region 1850 between power switch circuits 1840 and power supply source 1810 or power routing 1855. With the long paths of via tower 1815 and via tower 1845, there may be noticeable IR drop in TVDD before it gets to power switch circuits 1840 or VVDD when it gets to power routing 1855. Via tower 1815 and via tower 1845 may also present various physical blocking issues in transistor region 1850 that may affect physical design of routing/placement of components in device 1800.

FIG. 19 depicts a representation of a power switch circuit implementation where the power switch circuits are positioned in the BEOL layers of the device according to the various embodiments described herein. In the illustrated embodiment, power switch circuits 1950 are positioned in BEOL layers 1830. Power switch circuits 1950 may include any of the various embodiments of power switch circuits described herein or any combination of the various power switch circuits described herein.

As shown in FIG. 19 and described herein, with power switch circuits 1950 placed in BEOL layers 1830, TVDD from power supply source 1810 is provided to the power switch circuits through routing in the BEOL layers in combination with any number of vias between the different metal layers of routing. Thus, the length of the path between power supply source 1810 and power switch circuits 1950 is reduced compared to the path between the power supply source and power switch circuits 1840, shown in FIG. 18. This reduced path length reduces the IR drop for TVDD in getting to the power switch circuits.

Further, power switch circuits 1950 are connected to power routing 1855 directly from BEOL layers 1830 without any need for another via tower. This change reduces the length of the path between power switch circuits 1950 and functional circuits 1860 for VVDD, thus reducing the IR drop for VVDD.

Moving power switch circuits 1950 to BEOL layers 1830 removes the need for via towers in transistor region 1850 as well as removing the power switch circuits themselves from the transistor region. Accordingly, as shown in FIG. 19, transistor region 1850 now has via tower space 1915 and power switch circuits space 1940 available for additional circuitry where previously these spaces were occupied, as shown in FIG. 18. With via tower space 1915 and power switch circuits space 1940 now available for additional circuitry, device 1900 may have more functional capacity than available for device 1800.

### Example Manufacturing Method

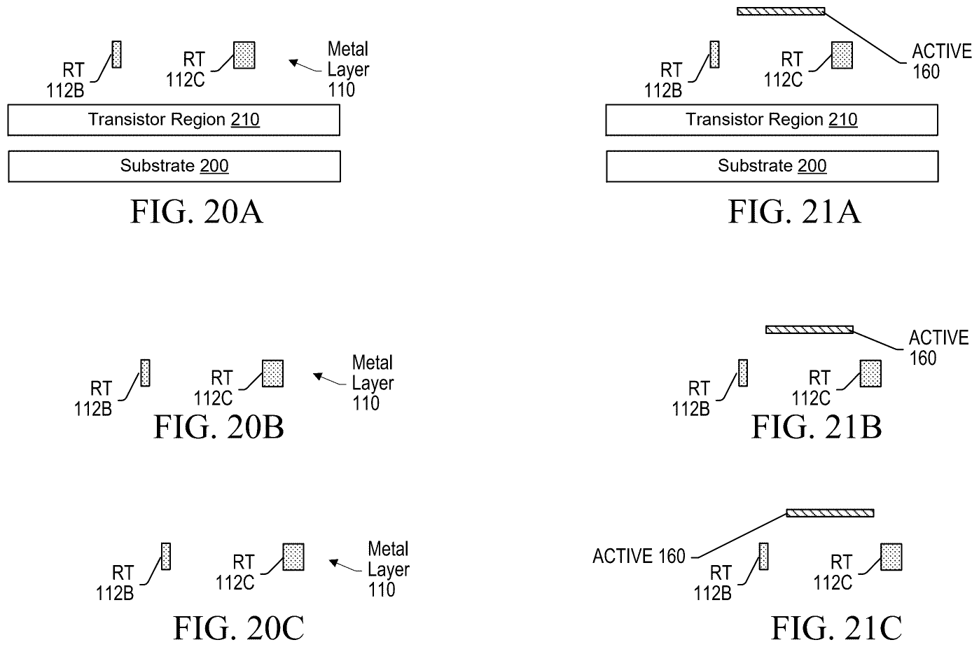

FIGS. 20-26 depict cross-sectional side-view representations of various possible steps in an exemplary embodiment of a method for manufacturing power switch circuit 150 between two topside metal layers of device 100 (as shown in FIGS. 1-4). Note that FIGS. 20-26 are shown along the same cross-sectional views of FIGS. 2-4 for showing results of manufacturing (e.g., process) steps to form power switch circuit 150 in device 100. Further note that the cross-sectional side-view representations in the “A” figures (e.g., FIGS. 20A, 21A, etc.) correspond to the cross-sectional view of FIG. 2 while the “B” figures (e.g., FIGS. 20B, 21B, etc.) correspond to the cross-sectional view of FIG. 3 and the “C” figures (e.g., FIGS. 20C, 21C, etc.) correspond to the cross-sectional view of FIG. 4. While the cross-sectional side-view representations in FIGS. 20-26 illustrate possible structural results of manufacturing steps for a power switch circuit being formed between two topside metal layers (e.g., BEOL layers), it should be understood that similar manufacturing steps may be applied to the additional embodiments of devices described herein. Furthermore, it is noted that FIGS. 20-26 depict cross-sectional side-view representations of intermediate structural results (e.g., structural end results for layers in a layer-by-layer manufacturing process) of manufacturing steps involved in forming a power switch circuit between topside metal layers.

In various embodiments, one or more semiconductor manufacturing processing steps are implemented to form the intermediate structural results or structural end results depicted in FIGS. 20-26. Examples of semiconductor manufacturing processing steps include, but are not limited to, wafer fabrication, etching (e.g., material removal), photolithography processing, deposition (e.g., material deposition), planarization (e.g., chemical mechanical planarization), ion implantation (e.g., doping), packaging, and packaging test (e.g., end product testing). Etching may include any of various etching techniques such as, but not limited to, wet etching, dry etching, plasma etching, and laser etching. Photolithography processing may include steps for mask deposition, irradiation (e.g., patterning), pattern transfer (including any related etching, deposition, or ion implantation steps), and mask removal (if necessary). Material deposition may include deposition processes such as, but not limited to, physical deposition, chemical deposition, chemical vapor deposition, evaporation, diffusion, spin coating, and electron beam deposition.

Any of the various semiconductor manufacturing processing steps mentioned above along with any related semiconductor manufacturing processing steps not explicitly disclosed may be implemented to arrive at the structures depicted in FIGS. 20-26 with the understanding that those skilled in the art would be able to determine a set of appropriate semiconductor manufacturing processing steps for implementing the depicted structures based on the present disclosure. Additionally, at some points throughout the present disclosure, semiconductor manufacturing processing steps may be explicitly recited in relation to specific structures. In such instances, it is understood that variations beyond the explicitly recited semiconductor manufacturing processing steps may be possible as known to those skilled in the art. Thus, while FIGS. 20-26 depict one exemplary embodiment for step-by-step manufacturing of devices described herein, additional embodiments for manufacturing devices described herein may be contemplated with modifications or alternatives that fall within the spirit or scope of the present disclosure where such modification or alternatives may include variations on the disclosed semiconductor manufacturing processing steps.

FIGS. 20A-C are cross-sectional side-view representations of a first manufacturing step of a power switch circuit positioned between two topside metal layers, according to some embodiments. In the illustrated embodiments, topside metal layer 110 is formed above transistor region 210 and substrate 200. Topside metal layer 110, as described herein, may be a topside BEOL metal layer vertically above transistor region 210 and substrate 200. In various embodiments, additional topside metal layers are positioned between topside metal layer 110 and transistor region 210. For instance, topside metal layer 110 may be a metal layer that is vertically further away from transistor region 210 than other topside metal layers. Embodiments may be contemplated where topside metal layer 110 is the topside metal layer closer to transistor region 210.

As described herein, topside metal layer 110 may include various routings. In the illustrated embodiments, routing 112B (e.g., routing for a control signal) and routing 112C (e.g., routing for a virtual power supply voltage (VVDD)) are shown along the cross-sectional side-view representations of FIGS. 20A-C. Turning to FIGS. 21A-C, cross-sectional side-view representations of a second manufacturing step of the power switch circuit positioned between two topside metal layers are shown, according to some embodiments. In certain embodiments, the second step includes forming a layer of any active regions for the power switch circuits. In various embodiments, active regions 160 are formed using thin channel materials such as, but not limited to, 2D (two-dimensional) materials, CNTs (carbon nano-tubes), and oxide semiconductors.

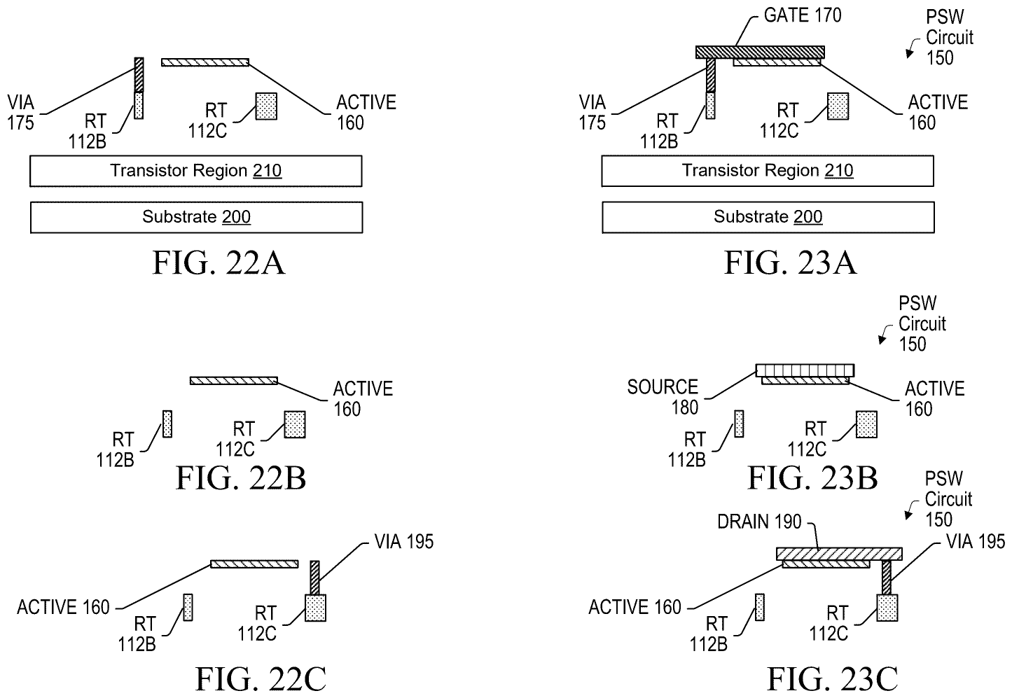

FIGS. 22A-C depict cross-sectional side-view representation of a third manufacturing step of the power switch circuit positioned between two topside metal layers, according to some embodiments. After forming active regions 160, in various embodiments, vias for connecting to topside metal layer 110 are formed in the third step. For instance, in the illustrated embodiment, via 175 is formed to connect to routing 112B, as shown in FIG. 22A, and via 195 is formed to connect to routing 112C, as shown in FIG. 22C.

FIGS. 23A-C depict cross-sectional side-view representations of a fourth manufacturing step of the power switch circuit positioned between two topside metal layers, according to some embodiments. In various embodiments, the fourth step includes formation of gate 170, source 180, and drain 190 associated with active region 160 of the power switch circuit. In certain embodiments, gate 170, source 180, and drain 190 are formed in the same layer, as shown in FIGS. 23A-C. Some embodiments may be contemplated, however, where one or more of gate 170, source 180, and drain 190 are formed in another layer.

In various embodiments, gate 170, source 180, and drain 190 may be formed using different material deposition steps though embodiments may be contemplated where the source and drain are formed in the same material deposition processing step. In certain embodiments, as shown in FIG. 23A, gate 170 is formed to connect to via 175, thereby providing connection to routing 112B (e.g., the control signal routing). As shown in FIG. 23C, drain 1990 may be formed to connect to via 195 and thereby routing 112C to enable output from the power switch circuit of the virtual power supply voltage (VVDD). In certain embodiments, power switch circuit 150 is substantially complete with the formation of gate 170, source 180, and drain 190 above active region 160, as shown in FIGS. 23A-C. For instance, power switch circuit 150 is largely complete except for an additional connection to source 180.

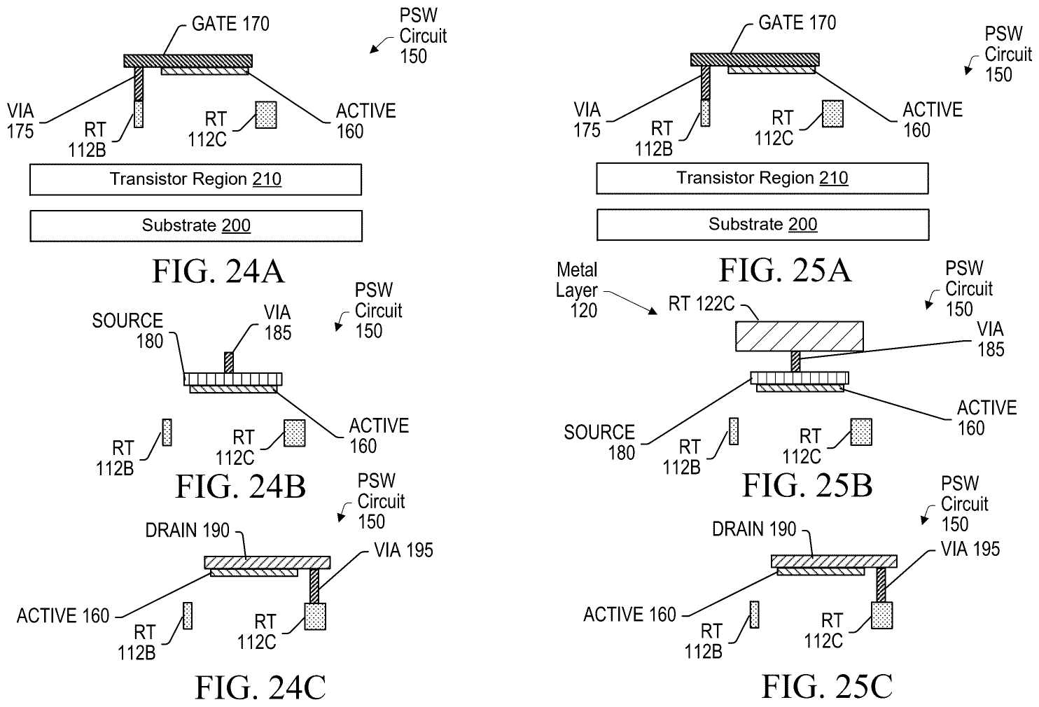

In some embodiments, a via is formed to source 180 of the power switch circuit. FIGS. 24A-C depict cross-sectional side-view representations of a fifth manufacturing step of the power switch circuit positioned between two topside metal layers, according to some embodiments. In the sixth step, as shown in FIG. 24B, via 185 is formed to source 180.

FIGS. 25A-C depict cross-sectional side-view representations of a final (sixth) manufacturing step of the power switch circuit positioned between two topside metal layers, according to some embodiments. In the substantially final step of formation of power switch circuit 150, topside metal layer 120 is formed above the power switch circuit with routing 122C in the topside metal layer coupled to source 180 in the power switch circuit by via 185. As described herein, routing 122C is routing for power supply voltage (“TVDD”) from a power supply source. Accordingly, connecting source 180 in power switch circuit 150 to routing 122C connects the source of power to the power switch circuit.

In various embodiments, topside metal layer 120 is a next topside metal layer after topside metal layer 110 (e.g., topside metal layer 120 is the topside metal layer next furthest from transistor region 210 after topside metal layer 110). Thus, power switch circuit 150 is formed between topside metal layer 110 and topside metal layer 120 by the steps shown in FIGS. 20-26. In certain embodiments, as described herein, topside metal layer 120 is the topside metal layer furthest from transistor region 210.

Note that similar steps for forming any of the power switch circuits described herein may be implemented based on the illustrated steps shown in FIGS. 20-25. Further, it should be noted that these steps may also form the basis of any process for forming a power switch circuit that has connections to routings in additional topside metal layers. For instance, the steps described may form the basis for forming power switch circuit 950, shown in FIGS. 9-12, which has connections to routings in lower metal layer 910 (e.g., a topside metal layer below topside metal layer 110).

It should be noted that in the various embodiments of the manufacturing steps depicted herein, the components of power switch circuit 150 may be enclosed inside a dielectric (e.g., dielectric 220 described herein). The dielectric may be implemented during the various manufacturing steps as would be known to a person of skill in the art. For instance, implementing the dielectric may include, for example, embedding or molding the components inside the dielectric material and/or forming components (such as vias or pillars) through the dielectric. While the dielectric may be formed in a single step, some embodiments may be contemplated where the dielectric is added in layers and/or during different steps in the manufacturing process. For instance, the dielectric may be formed in layers enclosing the components of power switch circuit 150 as they are formed in each of the steps shown in FIGS. 20-25.

### Example Computer System

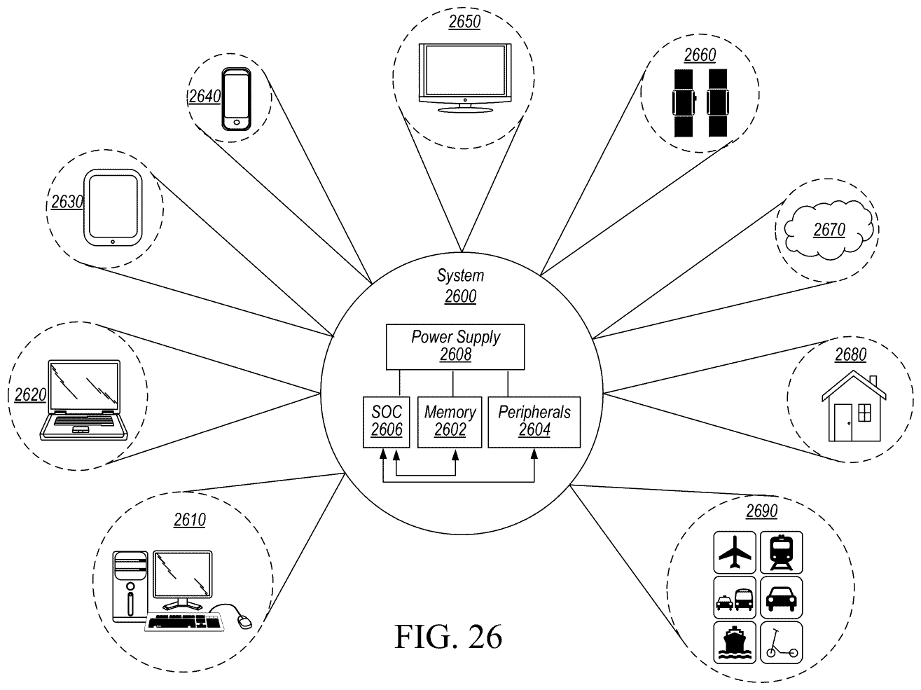

Turning next to FIG. 26, a block diagram of one embodiment of a system 2600 is shown that may incorporate and/or otherwise utilize the methods and mechanisms described herein. In the illustrated embodiment, the system 2600 includes at least one instance of a system on chip (SoC) 2606 which may include multiple types of processing units, such as a central processing unit (CPU), a graphics processing unit (GPU), or otherwise, a communication fabric, and interfaces to memories and input/output devices. In some embodiments, one or more processors in SoC 2606 includes multiple execution lanes and an instruction issue queue. In various embodiments, SoC 2606 is coupled to external memory 2602, peripherals 2604, and power supply 2608.

A power supply 2608 is also provided which supplies the supply voltages to SoC 2606 as well as one or more supply voltages to the memory 2602 and/or the peripherals 2604. In various embodiments, power supply 2608 represents a battery (e.g., a rechargeable battery in a smart phone, laptop or tablet computer, or other device). In some embodiments, more than one instance of SoC 2606 is included (and more than one external memory 2602 is included as well).

The memory 2602 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 2604 include any desired circuitry, depending on the type of system 2600. For example, in one embodiment, peripherals 2604 includes devices for various types of wireless communication, such as Wi-Fi, Bluetooth, cellular, global positioning system, etc. In some embodiments, the peripherals 2604 also include additional storage, including RAM storage, solid state storage, or disk storage. The peripherals 2604 include user interface devices such as a display screen, including touch display screens or multitouch display screens, keyboard or other input devices, microphones, speakers, etc.

As illustrated, system 2600 is shown to have application in a wide range of areas. For example, system 2600 may be utilized as part of the chips, circuitry, components, etc., of a desktop computer 2610, laptop computer 2620, tablet computer 2630, cellular or mobile phone 2640, or television 2650 (or set-top box coupled to a television). Also illustrated is a smartwatch and health monitoring device 2660. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 2600 may further be used as part of a cloud-based service(s) 2670. For example, the previously mentioned devices, and/or other devices, may access computing resources in the cloud (i.e., remotely located hardware and/or software resources). Still further, system 2600 may be utilized in one or more devices of a home 2680 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 26 is the application of system 2600 to various modes of transportation 2690. For example, system 2600 may be used in the control and/or entertainment systems of aircraft, trains, buses, cars for hire, private automobiles, waterborne vessels from private boats to cruise liners, scooters (for rent or owned), and so on. In various cases, system 2600 may be used to provide automated guidance (e.g., self-driving vehicles), general systems control, and otherwise. These any many other embodiments are possible and are contemplated. It is noted that the devices and applications illustrated in FIG. 26 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

### ***

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112 (f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a transistor region of an integrated circuit device, the transistor region being above a substrate in a vertical dimension perpendicular to the substrate;
a first metal layer located above the transistor region in the vertical dimension, the first metal layer having power supply routing coupled to a power supply for the integrated circuit device, the power supply routing being oriented along a first direction in a horizontal dimension;
a second metal layer located above the transistor region in the vertical dimension, the second metal layer having control signal routing oriented along a second direction in the horizontal dimension;
output power routing coupled to one or more circuits in the transistor region of the integrated circuit device; and
a power switch circuit positioned between the first metal layer and the second metal layer in the vertical dimension, wherein the power switch circuit includes:
an active region;
a gate formed over the active region;
a source region formed over the active region;
a drain region formed over the active region;
a first via coupling the gate to the control signal routing;
a second via coupling the source region to the power supply routing; and
a third via coupling the drain region to the output power routing.

2. The apparatus of claim 1, wherein the second direction in the horizontal dimension for the control signal routing is orthogonal to the first direction in the horizontal dimension for the power supply routing.

3. The apparatus of claim 1, wherein the output power routing is in the second metal layer.

4. The apparatus of claim 1, wherein the second direction in the horizontal dimension for the control signal routing is parallel to the first direction in the horizontal dimension for the power supply routing.

5. The apparatus of claim 4, further comprising a third metal layer positioned between the first metal layer and the second metal layer in the vertical dimension.

6. The apparatus of claim 5, wherein the first via and the third via pass through the third metal layer.

7. The apparatus of claim 1, wherein the output power routing is in the first metal layer, and wherein the output power routing is oriented in a third direction in the horizontal dimension parallel to the first direction.

8. The apparatus of claim 1, further comprising a fourth via coupling the source region to the power supply routing.

9. The apparatus of claim 1, wherein the power switch circuit further includes:
a second gate formed over the active region, wherein the second gate shares the drain region with the gate;
a second source region formed over the active region on an opposing side of the second gate from the drain region in the horizontal dimension;
a fourth via coupling the second gate to the control signal routing; and
a fifth via coupling the second source region to the power supply routing.

10. The apparatus of claim 9, wherein the power switch circuit further includes:
a third gate formed over the active region, wherein the third gate shares the second source region with the second gate;
a second drain region formed over the active region on an opposing side of the third gate from the second source region in the horizontal dimension;
a sixth via coupling the third gate to the control signal routing; and
a seventh via coupling the second drain region to the output power routing.

11. The apparatus of claim 1, wherein the power switch circuit is configured to receive a first power supply voltage from the power supply and generate a second power supply voltage based on the first power supply voltage.

12. The apparatus of claim 11, wherein the power switch circuit is configured to provide the second power supply voltage to the output power routing.

13. The apparatus of claim 1, wherein the second metal layer is below the first metal layer in the vertical dimension.

14. An apparatus, comprising:
a transistor region of an integrated circuit device, the transistor region being above a substrate in a vertical dimension perpendicular to the substrate;
a first metal layer located above the transistor region in the vertical dimension, the first metal layer having power supply routing coupled to a power supply for the integrated circuit device, the power supply routing being oriented along a first direction in a horizontal dimension;
a second metal layer located above the transistor region in the vertical dimension, the second metal layer having control signal routing and output power routing oriented along a second direction in the horizontal dimension, wherein the output power routing is coupled to one or more circuits in the transistor region of the integrated circuit device, and wherein the second direction is orthogonal to the first direction; and
a power switch circuit positioned between the first metal layer and the second metal layer in the vertical dimension, wherein the power switch circuit includes:
an active region;
a gate formed over the active region;
a source region formed over the active region;
a drain region formed over the active region;
a first via coupling the gate to the control signal routing;
a second via coupling the source region to the power supply routing; and
a third via coupling the drain region to the output power routing.

15. The apparatus of claim 14, wherein the control signal routing and the output power routing are oriented in parallel and displaced horizontally in the first direction.

16. The apparatus of claim 15, further comprising an additional routing positioned horizontally between the control signal routing and the output power routing in the first direction.

17. The apparatus of claim 14, wherein the second metal layer is below the first metal layer in the vertical dimension.

18. An apparatus, comprising:
a transistor region of an integrated circuit device, the transistor region being above a substrate in a vertical dimension perpendicular to the substrate;
a first metal layer located above the transistor region in the vertical dimension, the first metal layer having power supply routing coupled to a power supply for the integrated circuit device, the power supply routing being oriented along a first direction in a horizontal dimension;
a second metal layer located above the transistor region in the vertical dimension, the second metal layer having control signal routing and output power routing oriented along the first direction in the horizontal dimension, wherein the output power routing is coupled to one or more circuits in the transistor region of the integrated circuit device; and
a power switch circuit positioned between the first metal layer and the second metal layer in the vertical dimension, wherein the power switch circuit includes:
an active region;
a gate formed over the active region;
a source region formed over the active region;
a drain region formed over the active region;
a first via coupling the gate to the control signal routing;
a second via coupling the source region to the power supply routing; and
a third via coupling the drain region to the output power routing.

19. The apparatus of claim 18, further comprising a third metal layer positioned between the first metal layer and the second metal layer in the vertical dimension, wherein the first via and the third via pass through the third metal layer.

20. The apparatus of claim 18, wherein the control signal routing, the power supply routing, and the output power routing are oriented in parallel and displaced horizontally in a second direction orthogonal to the first direction.
